(19) United States
(12) Patent Application Publication
(10) Pub. No.: US 2026/0351329 A1
(43) Pub. Date: Nov. 5, 2026

(54) METHOD, APPARATUS, AND SYSTEM FOR PERFORMING FUNCTION COMPUTATION BASED ON IN-MEMORY COMPUTING

(71) Applicant: INSTITUTE OF MICROELECTRONICS, CHINESE ACADEMY OF SCIENCES, Beijing (CN)

(72) Inventors: Haiyang ZHOU, Beijing (CN); Hongyang HU, Beijing (CN); Zhi LI, Beijing (CN); Zhidao ZHOU, Beijing (CN); Xiaoxin XU, Beijing (CN); Yuanlu XIE, Beijing (CN); Chunmeng DOU, Beijing (CN)

(21) Appl. No.: 19/488,000

(22) PCT Filed: Sep. 22, 2023
(86) PCT No.: PCT/CN2023/120690

§ 371 Date: Nov. 25, 2025

(51) Int. Cl. G11C 27/00; G06F 7/50; G06F 7/523

(52) U.S. Cl. CPC G11C 27/005; G06F 7/50; G06F 7/523

(57) ABSTRACT

The present disclosure provides a method, apparatus, system, device, and storage medium for performing function computation based on in-memory computing, which may be applied to the field of artificial intelligence technology. The method includes: for a first power term in a first Taylor expansion of a first function to be computed, adjusting a first conductance value of a variable resistor on a word line corresponding to the first power term in a semiconductor memory device, according to a coefficient value of a first coefficient corresponding to the first power term; inputting a pulse voltage to the word line through the variable resistor in the semiconductor memory device, according to a value of the first power term, to obtain a first current output on a bit line; performing an analog-to-digital conversion on the first current to obtain a first current value corresponding to the first current; and determining a first computation result of the first function to be computed based on the first current value.

### TECHNICAL FIELD

The present disclosure relates to the field of artificial intelligence technology, and in particular to a method, apparatus, and system for performing function computation based on in-memory computing.

### BACKGROUND

With a rapid development of deep neural networks, the number of parameters and the computational workload have increased exponentially. To meet the computing power requirements of advanced neural network algorithms and thereby successfully complete artificial intelligence computation tasks, high energy consumption and significant hardware overhead are required.

In related technologies, graphics processing units (GPUs), which are computing systems based on the von Neumann architecture, are widely used to accelerate artificial intelligence algorithms. A characteristic of this architecture is a separation of storage and computation. During execution of a computation task, a computing unit is required to first access a memory, perform computation, and then write a computation result back to the memory. Because deep neural networks contain a large number of parameters, the computing unit is required to perform a large number of memory access operations, resulting in significant overhead of time and power consumption due to a large number of memory access.

In neural networks, the Softmax function is a generalization of logistic regression and thus may be used for multi-classification tasks. It is one of the most commonly used classification functions. However, at present, the Softmax function cannot be processed with high energy efficiency in the von Neumann architecture.

### SUMMARY

In view of the above problems, the present disclosure provides a method for performing function computation based on in-memory computing.

According to a first aspect of the present disclosure, a method for performing function computation based on in-memory computing is provided, including: for a first power term in a first Taylor expansion of a first function to be computed, adjusting a first conductance value of a variable resistor on a word line corresponding to the first power term in a semiconductor memory device, according to a coefficient value of a first coefficient corresponding to the first power term; inputting a pulse voltage to the word line through the variable resistor in the semiconductor memory device, according to a value of the first power term, to obtain a first current output on a bit line; performing an analog-to-digital conversion on the first current to obtain a first current value corresponding to the first current; and determining a first computation result of the first function to be computed based on the first current value.

According to an embodiment of the present disclosure, the adjusting a first conductance value of a variable resistor on a word line corresponding to the first power term in a semiconductor memory device according to a coefficient value of a first coefficient corresponding to the first power term includes: determining the variable resistor on the word line corresponding to the first power term, according to an exponent value of the first power term in the first Taylor expansion; and adjusting the first conductance value of the variable resistor corresponding to the first power term in the semiconductor memory device, according to the coefficient value of the first coefficient.

According to an embodiment of the present disclosure, the inputting a pulse voltage to the word line through the variable resistor in the semiconductor memory device according to a value of the first power term to obtain a first current output on a bit line includes: determining the word line corresponding to the first power term from a plurality of word lines, according to an exponent value of the first power term in the first Taylor expansion; inputting a pulse voltage corresponding to the coefficient value of the first coefficient to the word line corresponding to the first power term, according to the value of the first power term; and aggregating, for each bit line, currents on a plurality of word lines associated with the bit line to obtain the first current output on the bit line.

According to an embodiment of the present disclosure, the method for performing function computation based on in-memory computing further includes: for each first power term in the first Taylor expansion of the first function to be computed, adjusting a second conductance value of the variable resistor on the word line corresponding to the first power term in the semiconductor memory device, according to the value of the first power term; inputting a pulse voltage to the word line through the variable resistor in the semiconductor memory device, according to the coefficient value of the first coefficient corresponding to the first power term, to obtain a second current output on the bit line; performing an analog-to-digital conversion on the first current to obtain a second current value corresponding to the first current; and determining a second computation result of the first function to be computed based on the second current value.

According to an embodiment of the present disclosure, the adjusting a second conductance value of the variable resistor on the word line corresponding to the first power term in the semiconductor memory device according to the value of the first power term includes: determining the variable resistor on the word line corresponding to the first power term, according to an exponent value of the first power term in the first Taylor expansion; and adjusting the second conductance value of the variable resistor corresponding to the first power term in the semiconductor memory device, according to the value of the first power term in the first Taylor expansion.

According to an embodiment of the present disclosure, the first function to be computed includes a plurality of first Taylor expansions, and the determining a second computation result of the first function to be computed based on the second current value includes: summing a plurality of second current values to obtain the second computation result.

According to an embodiment of the present disclosure, the method for performing function computation based on in-memory computing further includes: determining, based on the second computation result, each second power term in a Maclaurin expansion of a second function to be computed; adjusting, for each second power term, a third conductance value of a variable resistor on a word line corresponding to the second power term in the semiconductor memory device, according to a value of the second power term; inputting a pulse voltage to the word line in the semiconductor memory device according to a coefficient value of a second coefficient corresponding to the second power term, to obtain a third current output on the bit line; performing an analog-to-digital conversion on the third current to obtain a third current value corresponding to the third current; and determining a third computation result based on the third current value and the first computation result.

According to an embodiment of the present disclosure, the method for performing function computation based on in-memory computing further includes: determining, based on the third computation result, each third power term in a second Taylor expansion of a third function to be computed; adjusting, for each third power term, a fourth conductance value of a variable resistor on a word line corresponding to the third power term in the semiconductor memory device, according to a coefficient value of a third coefficient corresponding to the third power term; inputting a pulse voltage to the word line in the semiconductor memory device according to a value of the third power term, to obtain a fourth current output on the bit line; performing an analog-to-digital conversion on the fourth current to obtain a fourth current value corresponding to the fourth current; and determining a fourth computation result of the third function to be computed based on the fourth current value.

In a second aspect of the present disclosure, an apparatus for performing function computation based on in-memory computing is provided, including: a first adjustment module configured to adjust a first conductance value of a variable resistor on a word line corresponding to a first power term in a semiconductor memory device, according to a coefficient value of a first coefficient corresponding to the first power term; a first input module configured to input a pulse voltage to the word line through the variable resistor in the semiconductor memory device, according to a value of the first power term, to obtain a first current output on a bit line; a first conversion module configured to perform an analog-to-digital conversion on the first current to obtain a first current value corresponding to the first current; and a first determination module configured to determine a first computation result of the first function to be computed based on the first current value.

In a third aspect of the present disclosure, a system for performing function computation based on in-memory computing is provided, including: a semiconductor memory device, including a word line and a bit line, where a variable resistor is provided on the word line; the semiconductor memory device is configured to receive a pulse voltage on the bit line and to obtain, through the variable resistor on the word line, a first current output on the bit line, a first conductance value of the variable resistor is adjusted according to a coefficient value of a first coefficient corresponding to a first power term, and a voltage value of the pulse voltage is determined according to a value of the first power term; an analog-to-digital converter configured to receive the first current transmitted from the semiconductor memory device, and to perform an analog-to-digital conversion on the first current to obtain a first current value corresponding to the first current; and a calculator configured to receive the first current value transmitted from the analog-to-digital converter, and to determine a first computation result of a first function to be computed based on the first current value.

In a fourth aspect of the present disclosure, an electronic device is provided, including: one or more processors; and a memory for storing one or more programs, wherein the one or more programs are configured to, when executed by the one or more processors, cause the one or more processors to implement the method for performing function computation based on in-memory computing as described above.

In a fifth aspect of the present disclosure, a computer-readable storage medium having executable instructions therein is provided, and the instructions are configured to, when executed by a processor, cause the processor to implement the method for performing function computation based on in-memory computing as described above.

In a sixth aspect of the present disclosure, a computer program product containing a computer program is provided, where the computer program is configured to, when executed by a processor, cause the processor to implement the method for performing function computation based on in-memory computing as described above.

According to embodiments of the present disclosure, a resistive random access memory (RRAM) is used to perform natural exponential operations. Since the polynomial coefficients in the Taylor expansion are constants, reuse of fixed constants is achieved by setting the conductance value of the variable resistor in the semiconductor memory device according to the coefficient value of the first coefficient corresponding to the first power term. Moreover, due to the multi-bit storage characteristic of RRAM, the advantages of in-memory computing that allow high-parallelism matrix-vector multiplication may be achieved, while avoiding the operation of determining the voltage value of the pulse voltage input to the word line through multiple access, thereby reducing the number of memory access. Furthermore, this also mitigates the problem of low computational efficiency caused by repeatedly reading from memory space before computation in conventional computer architectures.

### BRIEF DESCRIPTION OF THE DRAWINGS

The above and other objectives, features, and advantages of the present disclosure will become more apparent from the following description with reference to the accompanying drawings, in which:

FIG. 1 schematically shows an application scenario diagram of a method, apparatus, device, medium, and program product for performing function computation based on in-memory computing according to an embodiment of the present disclosure;

FIG. 2 schematically shows a flowchart of a method for performing function computation based on in-memory computing according to an embodiment of the present disclosure;

FIG. 3 schematically shows a structural diagram of a system for performing function computation based on in-memory computing according to an embodiment of the present disclosure;

FIG. 4 schematically shows a flowchart of a method for performing Softmax function computation based on in-memory computing according to an embodiment of the present disclosure;

FIG. 5 schematically shows a flowchart of a method for performing function computation based on in-memory computing according to another embodiment of the present disclosure;

FIG. 6 schematically shows a structural diagram of a system for performing function computation based on in-memory computing according to another embodiment of the present disclosure;

FIG. 7 schematically shows a structural block diagram of an apparatus for performing function computation based on in-memory computing according to an embodiment of the present disclosure; and

FIG. 8 schematically shows a block diagram of an electronic device suitable for performing function computation based on in-memory computing according to an embodiment of the present disclosure.

### DETAILED DESCRIPTION OF EMBODIMENTS

Embodiments of the present disclosure will be described below with reference to the accompanying drawings. However, it should be understood that these descriptions are merely exemplary and are not intended to limit the scope of the present disclosure. In the following detailed description, numerous specific details are set forth to provide a thorough understanding of embodiments of the present disclosure. It will be apparent, however, that one or more embodiments may be practiced without these specific details. Moreover, descriptions of well-known structures and techniques are omitted to avoid unnecessarily obscuring the concepts of the present disclosure.

The terminology used herein is for the purpose of describing specific embodiments only and is not intended to limit the present disclosure. The terms “include,” “contain,” and similar expressions indicate the presence of stated features, steps, operations, and/or components, but do not preclude the presence or addition of one or more other features, steps, operations, or components.

All terms (including technical and scientific terms) used herein have the meanings commonly understood by those skilled in the art, unless otherwise defined. It should be noted that the terms used herein should be interpreted as having a meaning consistent with the context of the specification and should not be interpreted in an idealized or overly rigid manner.

When expressions such as “at least one of A, B, and C” are used, they should generally be interpreted as commonly understood by those skilled in the art (for example, “a system having at least one of A, B, and C” should be construed to include, but not be limited to, a system having only A, only B, only C, both A and B, both A and C, both B and C, and/or all of A, B, and C.).

In the technical solutions of the present disclosure, the user information (including but not limited to user personal information, user image information, and user device information such as location information, etc.) and data (including but not limited to data for analysis, data for storage, data for display, etc.) involved are all information and data authorized by the user or fully authorized by all relevant parties. The collection, storage, use, processing, transmission, provision, disclosure, application, and other processing of relevant data comply with the relevant laws, regulations, and standards of relevant countries and regions, adopt necessary confidentiality measures, do not violate public order and good customs, and provide corresponding operation interfaces for users to choose authorization or refusal.

In the technical solutions of embodiments of the present disclosure, the acquisition or collection of user personal information has been authorized or allowed by users.

During the implementation of the present disclosure, it has been found that the computation of the Softmax function involves three operators: natural exponentiation, summation of natural exponentials, and division, in which the computation of the natural exponentiation is the core computation. The conventional computation method is to expand the natural exponential into a Taylor expansion, compute the expansion terms one by one using a digital multiplier, and then accumulate the expansion terms using a digital adder to obtain a result. The polynomial coefficients in the Taylor expansion are fixed constants and should be reused. However, in the von Neumann architecture, these constants cannot be effectively reused in the computation process using the above computation method. Furthermore, calculating natural exponentials using conventional digital circuits requires huge hardware area overhead.

An embodiment of the present disclosure provides a method for performing function computation based on in-memory computing, including: for a first power term in a first Taylor expansion of a first function to be computed, adjusting a first conductance value of a variable resistor on a word line corresponding to the first power term in a semiconductor memory device, according to a coefficient value of a first coefficient corresponding to the first power term; inputting a pulse voltage to the word line through the variable resistor in the semiconductor memory device according to a value of the first power term, to obtain a first current output on a bit line; performing an analog-to-digital conversion on the first current to obtain a first current value corresponding to the first current; and determining a first computation result of the first function to be computed based on the first current value.

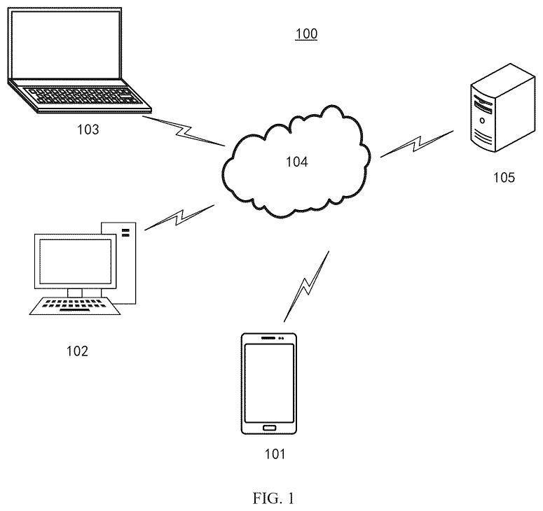

FIG. 1 schematically shows an application scenario diagram of a method, apparatus, device, medium, and program product for performing function computation based on in-memory computing according to an embodiment of the present disclosure.

As shown in FIG. 1, an application scenario 100 according to this embodiment may include a first terminal device 101, a second terminal device 102, a third terminal device 103, a network 104, and a server 105. The network 104 is a medium for providing a communication link between the first terminal device 101, the second terminal device 102, the third terminal device 103, and the server 105. The network 104 may include various types of connections, such as wired, wireless communication links, or optical fiber cables, etc.

At least one of the first terminal device 101, the second terminal device 102, and the third terminal device 103 may be used by a user to interact with the server 105 through the network 104 to receive or send messages, etc. The first terminal device 101, the second terminal device 102, and the third terminal device 103 may be installed with various communication client applications, such as shopping applications, web browser applications, search applications, instant messaging tools, email clients, social platform software, etc. (just for example).

The first terminal device 101, the second terminal device 102, and the third terminal device 103 may be various electronic devices having a display screen and supporting web browsing, including but not limited to smartphones, tablet computers, laptop computers, desktop computers, etc.

The server 105 may be a server providing various services, such as a background management server that supports websites browsed by users through the first terminal device 101, the second terminal device 102, and the third terminal device 103 (just for example). The background management server may analyze and process user requests and other data received, and return processing results (such as webpages, information, or data acquired or generated according to user requests) to the terminal device.

It should be noted that the method for performing function computation based on in-memory computing provided by embodiments of the present disclosure may generally be performed by the server 105. Accordingly, the apparatus for performing function computation based on in-memory computing provided by embodiments of the present disclosure may generally be disposed in the server 105. The method for performing function computation based on in-memory computing provided by embodiments of the present disclosure may also be performed by a server or server cluster different from the server 105 and capable of communicating with the first terminal device 101, the second terminal device 102, the third terminal device 103, and/or the server 105. Accordingly, the apparatus for performing function computation based on in-memory computing provided by embodiments of the present disclosure may also be disposed in a server or server cluster different from the server 105 and capable of communicating with the first terminal device 101, the second terminal device 102, the third terminal device 103, and/or the server 105.

It should be understood that the number of terminal devices, networks, and servers in FIG. 1 is merely schematic. According to implementation needs, any number of terminal devices, networks, and servers may be provided.

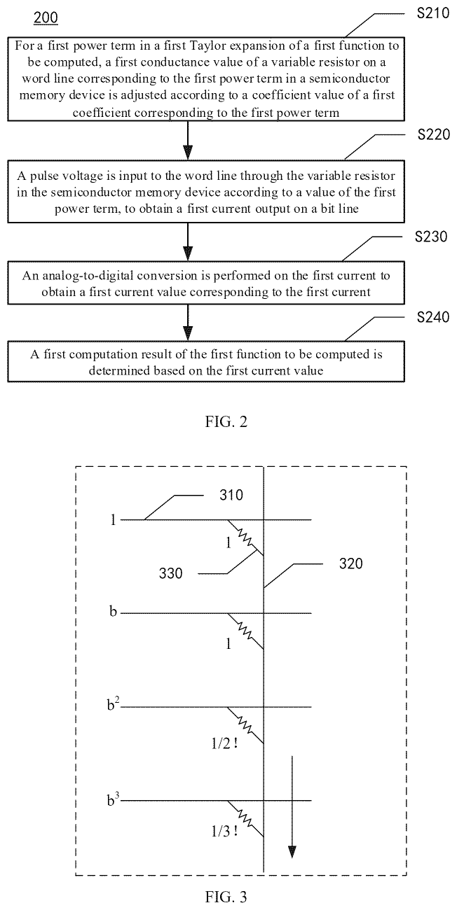

Based on the scenario described in FIG. 1, the method for performing function computation based on in-memory computing according to embodiments of the present disclosure will be described in detail below with reference to FIG. 2 to FIG. 4.

FIG. 2 schematically shows a flowchart of a method for performing function computation based on in-memory computing according to an embodiment of the present disclosure.

As shown in FIG. 2, a method 200 for performing function computation based on in-memory computing in this embodiment includes operation S210 to operation S240.

In operation S210, for a first power term in a first Taylor expansion of a first function to be computed, a first conductance value of a variable resistor on a word line corresponding to the first power term in a semiconductor memory device is adjusted according to a coefficient value of a first coefficient corresponding to the first power term.

According to an embodiment of the present disclosure, the semiconductor memory device may include N word lines and one or more bit lines, and each word line may include one variable resistor. The number of terms in the first Taylor expansion may be determined according to the number of word lines in the semiconductor memory device. The N word lines correspond one-to-one with the N terms of the first function to be computed. The first conductance value of the variable resistor is set to the coefficient value of the first coefficient corresponding to the first power term associated with that variable resistor. Here, the first coefficient of the first function to be computed may be the coefficient value of each term in the first function to be computed, and the first coefficients correspond one-to-one with the first power terms.

According to an embodiment of the present disclosure, the semiconductor memory device may take a resistive random access memory (RRAM). RRAM is a type of non-volatile memory in which a metal oxide is sandwiched between two electrodes, thereby achieving low power consumption and high-speed rewriting. By applying a pulse voltage to the metal oxide thin film, a large resistance difference may be generated to store “0” and “1”. Furthermore, because RRAM may achieve multi-bit storage by adjusting resistance states, storing multiple bits of data may be achieved with reduced hardware overhead.

In operation S220, a pulse voltage is input to the word line through the variable resistor in the semiconductor memory device according to a value of the first power term, to obtain a first current output on a bit line.

According to an embodiment of the present disclosure, the pulse voltage is determined according to the value of the first power term. After the pulse voltages are input to the respective word lines, currents are generated through the variable resistors on the word lines, and the currents are aggregated on the bit line to obtain the first current.

In operation S230, an analog-to-digital conversion is performed on the first current to obtain a first current value corresponding to the first current.

According to an embodiment of the present disclosure, an analog-to-digital conversion is performed on the first current to convert a current signal into a digital signal, thereby obtaining the first current value.

In operation S240, a first computation result of the first function to be computed is determined based on the first current value.

According to an embodiment of the present disclosure, based on Kirchhoff's law and Ohm's law, the first currents aggregated on the bit line may represent a value of the polynomial computed on the bit line. Therefore, the value corresponding to the target power term in the first function to be computed may be obtained according to the current value of the first current. After the pulse voltages are input, the first current may be directly generated on the bit line without the need for manual summation operations, which avoids the time and power consumption overhead caused by multiple memory access in the von Neumann architecture, and enables in-situ computation within the memory, thereby achieving in-memory computing.

FIG. 3 schematically shows a structural diagram of a semiconductor memory device for performing function computation based on in-memory computing according to an embodiment of the present disclosure.

As shown in FIG. 3, the semiconductor memory device for performing function computation based on in-memory computing in this embodiment includes a word line 310, a bit line 320, and a variable resistor 330.

According to an embodiment of the present disclosure, the semiconductor memory device shown in FIG. 3 may be used to calculate e^{x}^{₀}≈1+x₀+ 1/2!x₀²+ 1/3!x₀³. Four word lines may correspond one-to-one with the four first power terms in the Taylor expansion of e^{x}^{₀}. According to the values of the first power terms, the first conductance values of the variable resistors on the four word lines are respectively set to 1, 1, 1/2!, and 1/3!. Further, according to the coefficient values of the first coefficients corresponding to the first power terms, pulse voltages having magnitudes x₀⁰, x₀¹, x₀², and x₀³ are respectively input to the word lines through the variable resistors in the semiconductor memory device. Because the current value=voltage value×conductance value, the current values on the four word lines are respectively 1, x₀, 1/2!x₀², and 1/3!x₀³. A current value having a magnitude of 1+x₀+ 1/2!x₀²+ 1/3!x₀³≈e^{x}^{₀} is obtained on the bit line, and the value of e^{x}^{₀} may be determined according to the magnitude of the current value.

According to embodiments of the present disclosure, a resistive random access memory (RRAM) is used to perform natural exponential operations. Since the polynomial coefficients in the Taylor expansion are constants, reuse of fixed constants is achieved by setting the conductance value of the variable resistor in the semiconductor memory device according to the coefficient value of the first coefficient corresponding to the first power term. Moreover, due to the multi-bit storage characteristic of RRAM, the advantages of in-memory computing that allow high-parallelism matrix-vector multiplication may be achieved, while avoiding the operation of determining the voltage value of the pulse voltage input to the word line through multiple access, thereby reducing the number of memory access. Furthermore, this also mitigates the problem of low computational efficiency caused by repeatedly reading from memory space before computation in conventional computer architectures.

According to an embodiment of the present disclosure, adjusting the first conductance value of the variable resistor on the word line corresponding to the first power term in the semiconductor memory device according to the coefficient value of the first coefficient corresponding to the first power term includes: determining the variable resistor on the word line corresponding to the first power term according to an exponent value of the first power term in the first Taylor expansion; and adjusting the first conductance value of the variable resistor corresponding to the first power term in the semiconductor memory device according to the coefficient value of the first coefficient.

According to an embodiment of the present disclosure, the first function to be computed may take the first N terms in the Taylor expansion of the function e^{x}, where the first power terms, arranged in ascending order of exponents, include x⁰, x¹, x², . . . , x^{N-2}, x^{N-1}. First, a corresponding relationship between the variable resistors on the word lines and the respective terms in the first Taylor expansion is determined, such that a term with the exponent value of n corresponds to an (n+1)^{th} word line. Then, the conductance value of the variable resistor corresponding to the respective term is adjusted according to the coefficient value of that term.

According to an embodiment of the present disclosure, inputting a pulse voltage to the word line through the variable resistor in the semiconductor memory device according to the value of the first power term to obtain the first current output on the bit line includes: determining, according to an exponent value of the first power term in the first Taylor expansion, the word line corresponding to the first power term from a plurality of word lines; inputting, according to the value of the first power term, a pulse voltage corresponding to the coefficient value of the first coefficient to the word line corresponding to the first power term; and aggregating, for each bit line, the currents on a plurality of word lines associated with the bit line to obtain the first current output on the bit line.

According to an embodiment of the present disclosure, because the corresponding relationship between the variable resistors on the word lines and the respective first power terms has been determined, a pulse voltage having a magnitude corresponding to the value of a power term may be input to the word line corresponding to that term to obtain the current output on the word line. The currents from all word lines associated with a bit line are aggregated on that bit line to obtain the first current on the bit line.

According to an embodiment of the present disclosure, the method for performing function computation based on in-memory computing further includes: for the first power term in the first Taylor expansion of the first function to be computed, adjusting a second conductance value of the variable resistor on the word line corresponding to the first power term in the semiconductor memory device, according to the value of the first power term; inputting a pulse voltage to the word line through the variable resistor in the semiconductor memory device according to the coefficient value of the first coefficient corresponding to the first power term, to obtain a second current output on the bit line; performing an analog-to-digital conversion on the first current to obtain a second current value corresponding to the first current; and determining a second computation result of the first function to be computed based on the second current value.

According to an embodiment of the present disclosure, adjusting the second conductance value of the variable resistor on the word line corresponding to the first power term in the semiconductor memory device according to the value of the first power term includes: determining, according to the exponent value of the first power term in the first Taylor expansion, the variable resistor on the word line corresponding to the first power term; and adjusting, according to the value of the first power term in the first Taylor expansion, the second conductance value of the variable resistor corresponding to the first power term in the semiconductor memory device.

According to an embodiment of the present disclosure, the first function to be computed may take the first N terms in the Taylor expansion of the function e^{x}, where the first power terms, arranged in ascending order of exponents, include x⁰, x¹, x², . . . , x^{N-2}, x^{N-1} First, a corresponding relationship between the variable resistors on the word lines and the respective terms in the first Taylor expansion is determined, such that a term with the exponent value of n corresponds to an (n+1)^{th} word line. Then, the conductance value of the variable resistor corresponding to the respective term is adjusted according to the exponent of that term and a value of an independent variable.

According to an embodiment of the present disclosure, the first function to be computed includes a plurality of first Taylor expansions, and determining the second computation result of the first function to be computed based on the second current value includes summing a plurality of second current values to obtain the second computation result.

According to an embodiment of the present disclosure, in a case where a plurality of bit lines are provided in the semiconductor memory device, after a plurality of second currents on the respective bit lines are obtained and are subjected to an analog-to-digital conversion to obtain second current values, the plurality of second current values may be summed to obtain a second computation result representing a sum of function values of the plurality of Taylor expansions in the first function to be computed that is computed on the semiconductor memory device.

According to an embodiment of the present disclosure, because the conductance value of the variable resistor on the word line is set to a power term in a term of the first function to be computed corresponding to that variable resistor, and the pulse voltage input to the word line is determined according to the coefficient value of the first coefficient, the magnitude of the current generated on the word line is a result of that term.

For example, in a case where the first function to be computed takes the first N terms in the Taylor expansion of e^{x}, and x=x₀, the magnitude of the second current value obtained by performing an analog-to-digital conversion on the second current on the corresponding bit line is equal to the result of exo In a case where three bit lines are provided in the semiconductor memory device and x takes x₀, x₁, and x₂ respectively, by summing the second current values of the three bit lines, a computation result of e^{x}^{₀}+e^{x}^{₁}+e^{x}^{₂} may be obtained. Therefore, the semiconductor memory device may be used to compute a value of

$${\sum }_{j = 1}^{d} {e}^{{x}_{j}} ,$$

where d is the number of bit lines in the semiconductor memory device.

According to an embodiment of the present disclosure, the computation of the Softmax function is expressed as Equation (1):

$$softmax ( {x}_{i} ) = \frac{{e}^{{x}_{i}}}{{\sum }_{j = 1}^{d} {e}^{{x}_{j}}} \qquad ( 1 )$$

After obtaining the second computation result of the function

$${\sum }_{j = 1}^{d} {e}^{{x}_{j}}$$

from the first current value, a division operation is performed according to Equation (2):

$$ln ( softmax ( {x}_{i} ) ) = ln \frac{{e}^{{x}_{i}}}{{\sum }_{j = 1}^{d} {e}^{{x}_{j}}} = {ln e}^{{x}_{i}} - ln {\sum }_{j = 1}^{d} {e}^{{x}_{j}} \qquad ( 2 )$$

where lne^{x}^{ᵢ}=xᵢ. Thus, the division operation may be transformed into the computation of

$$ln {\sum }_{j = 1}^{d} {e}^{{x}_{j}} .$$

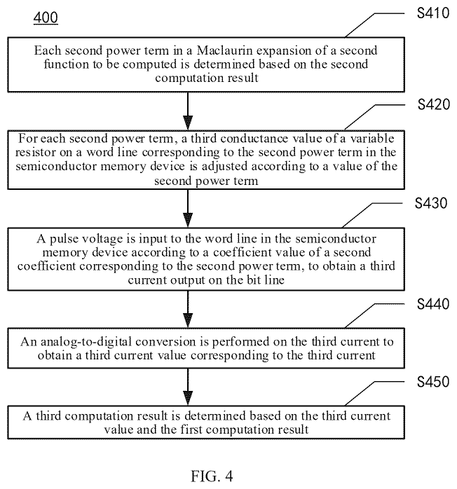

FIG. 4 schematically shows a flowchart of a method for performing function computation based on in-memory computing according to an embodiment of the present disclosure.

As shown in FIG. 4, a method 400 for performing function computation based on in-memory computing in this embodiment includes operation S410 to operation S450.

In operation S410, each second power term in a Maclaurin expansion of a second function to be computed is determined based on the second computation result.

According to an embodiment of the present disclosure, a base of the second power term in the second function to be computed may be numerically equal to the second computation result.

In operation S420, for each second power term, a third conductance value of a variable resistor on a word line corresponding to the second power term in the semiconductor memory device is adjusted according to a value of the second power term.

According to an embodiment of the present disclosure, the semiconductor memory device may include M word lines and one bit line, where each word line may include one variable resistor. The number of terms in the second function to be computed may be determined according to the number of word lines in the semiconductor memory device. Thus, the M word lines correspond one-to-one with the M terms in the second function to be computed. The third conductance value of the variable resistor is set to the value of the second power term in the second function to be computed corresponding to that variable resistor.

In operation S430, a pulse voltage is input to the word line in the semiconductor memory device according to a coefficient value of a second coefficient corresponding to the second power term, to obtain a third current output on the bit line.

According to an embodiment of the present disclosure, the second coefficient of the second function to be computed may be the coefficient value of each term in the second function to be computed, and the second coefficients correspond one-to-one with the second power terms. The pulse voltage on each word line is determined according to the coefficient value of the second coefficient. After a pulse voltage is input to the respective word line, a current is generated through the variable resistor on the word line. The currents on a plurality of word lines associated with a bit line are aggregated to obtain the third current on that bit line.

In operation S440, an analog-to-digital conversion is performed on the third current to obtain a third current value corresponding to the third current.

According to an embodiment of the present disclosure, an analog-to-digital conversion is performed on the third current to convert a current signal into a digital signal, thereby obtaining the third current value.

In operation S450, a third computation result is determined based on the third current value and the first computation result.

According to an embodiment of the present disclosure, the third computation result is obtained by subtracting the third current value from the first computation result, where the subtraction may be performed using a current differential amplifier.

According to an embodiment of the present disclosure, a value of a natural logarithm having a base equal to the second computation result may be calculated using a semiconductor memory device. By using the property of logarithmic functions, the division may be transformed into subtraction for computation, thereby avoiding shift and add operations required for division in conventional computer architectures, and improving computational efficiency.

According to an embodiment of the present disclosure, the second function to be computed may take the first M terms in the Maclaurin expansion of ln(1+a), where (1+a) may be numerically equal to the first computation result. Thus, the second power terms, arranged in ascending order of exponents, include (1+a)¹, (1+a)², . . . , (1+a)^{M-1}, (1+a)^{M}. First, a corresponding relationship between the variable resistors on the word lines and the respective second power terms in the Maclaurin expansion is determined according to the exponents of the second power terms, such that an m^{th} second power term corresponds to the variable resistor on an m^{th} word line. Then, the third conductance value of the variable resistor corresponding to the respective term is adjusted according to the value of the power term of that term.

For example, if a term in the second function to be computed is (⅓) (1+a)³ and the second computation result is p, then the conductance value of the variable resistor on the word line corresponding to that term is set to p³, the pulse voltage input to the word line is ⅓, and the magnitude of the current generated on the word line is (⅓) (p³), which is equal to the computation result of that term. The magnitude of the third current value obtained on the bit line is

$$ln {\sum }_{j = 1}^{d} {e}^{{x}_{j}} .$$

The third computation result may be obtained by subtracting the third current value from the first computation result on the bit line corresponding to x=xᵢ.

According to an exemplary embodiment of the present disclosure, a method for performing Softmax function computation based on in-memory computing may be further provided. On the basis of operations S410 to S450 as shown in FIG. 4, the method may further include: determining, based on the third computation result, each third power term in a second Taylor expansion of a third function to be computed; adjusting, for each third power term, a fourth conductance value of a variable resistor on a word line corresponding to the third power term in the semiconductor memory device, according to a coefficient value of a third coefficient corresponding to the third power term; inputting a pulse voltage to the word line in the semiconductor memory device according to a value of the third power term, to obtain a fourth current output on the bit line; performing an analog-to-digital conversion on the fourth current to obtain a fourth current value corresponding to the fourth current; and determining a fourth computation result of the third function to be computed based on the fourth current value.

According to an embodiment of the present disclosure, after obtaining the third computation result from the first computation result and the third current value, the computation of the Softmax function may be completed according to Equation (3):

$${e}^{ln ( softmax ( {x}_{i} ) )} = softmax ( {x}_{i} ) = {e}^{{x}_{i} - ln {\sum }_{j = 1}^{d} {e}^{{x}_{j}}} \qquad ( 3 )$$

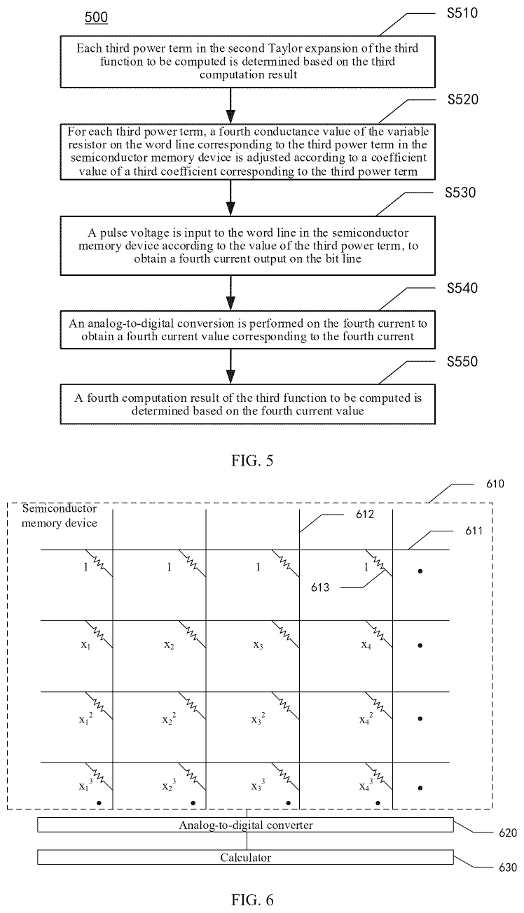

FIG. 5 schematically shows a flowchart of a method for performing Softmax function computation based on in-memory computing according to an embodiment of the present disclosure.

As shown in FIG. 5, a method 500 for performing Softmax function computation based on in-memory computing in this embodiment includes operation S510 to operation S550.

In operation S510, each third power term in the second Taylor expansion of the third function to be computed is determined based on the third computation result.

According to an embodiment of the present disclosure, a base of the third power term of the third function to be computed may be numerically equal to the third computation result.

In operation S520, for each third power term, a fourth conductance value of the variable resistor on the word line corresponding to the third power term in the semiconductor memory device is adjusted according to a coefficient value of a third coefficient corresponding to the third power term.

According to an embodiment of the present disclosure, the third coefficient of the third function to be computed may be the coefficient value of each term in the third function to be computed, and the third coefficients correspond one-to-one with the third power terms. The semiconductor memory device may include P word lines and one bit line, where each word line may include one variable resistor. The number of terms in the third function to be computed may be determined according to the number of word lines in the semiconductor memory device. Thus, the P word lines correspond one-to-one with the P terms in the third function to be computed. The conductance value of the variable resistor is set to the coefficient value of the third coefficient.

In operation S530, a pulse voltage is input to the word line in the semiconductor memory device according to the value of the third power term, to obtain a fourth current output on the bit line.

According to an embodiment of the present disclosure, the pulse voltage on the word line is determined according to the value of the third power term of the term in the third function to be computed corresponding to the variable resistor. After a pulse voltage is input to a word line, a current is generated through the variable resistor on the word line. The currents on a plurality of word lines associated with a bit line are aggregated to obtain the fourth current on that bit line.

In operation S540, an analog-to-digital conversion is performed on the fourth current to obtain a fourth current value corresponding to the fourth current.

According to an embodiment of the present disclosure, an analog-to-digital conversion is performed on the fourth current to convert a current signal into a digital signal, thereby obtaining the fourth current value.

In operation S550, a fourth computation result of the third function to be computed is determined based on the fourth current value.

According to an embodiment of the present disclosure, the fourth computation result of the third function to be computed may be numerically equal to the fourth current value.

According to an embodiment of the present disclosure, a semiconductor memory device is used to compute a value having a natural constant as the base and the third computation result as the exponent. By using an inverse function relationship between logarithmic functions and exponential functions, the result of the Softmax function may be obtained. Moreover, since the coefficient in the Taylor expansion of the natural exponential function is set as the fourth conductance value of the variable resistor, the computation result may be obtained merely by changing the voltage value of the pulse voltage on the word line, thereby achieving reuse of constants.

According to an embodiment of the present disclosure, the fourth computation result of the third function to be computed may be calculated using the system for performing function computation based on in-memory computing as shown in FIG. 3. According to an embodiment of the present disclosure, the third function to be computed may take the first P terms in the Taylor expansion of e^{b}, where b may be numerically equal to the second computation result. Thus, the third parameters, arranged in ascending order of exponents, include b⁰, b¹, . . . , b^{(P-2)}, b^{(P-1)}. First, the corresponding relationship between the variable resistors on the word lines and the respective terms in the Taylor expansion is determined. Then, the conductance value of the variable resistor corresponding to the respective term is adjusted according to the coefficient value of that term.

For example, if a term in the third function to be computed is (⅙) (b³), then the pulse voltage input to the word line corresponding to that term is b³, the conductance value of the variable resistor on the word line is set to ⅙, and the magnitude of the current generated on the word line is (⅙) (b³), which is equal to the computation result of that term. The magnitude of the third current value obtained on the bit line is

$${e}^{{x}_{i} - ln {\sum }_{j = 1}^{d} {e}^{{x}_{j}}} ,$$

thus obtaining the result of softmax (xᵢ).

FIG. 6 schematically shows a structural diagram of a system for performing function computation based on in-memory computing according to another embodiment of the present disclosure.

As shown in FIG. 6, a system for performing function computation based on in-memory computing in this embodiment includes a semiconductor memory device 610, an analog-to-digital converter 620, and a calculator 630.

The semiconductor memory device includes word lines 611 and bit lines 612, and variable resistors 613 are provided on the word lines. The semiconductor memory device is configured to receive a pulse voltage on a bit line, and obtain a first current output on the bit line through the variable resistor on the word line. The first conductance value of the variable resistor is adjusted according to the value of the first power term. The voltage value of the pulse voltage is determined according to the coefficient value of the first coefficient corresponding to the first power term.

The analog-to-digital converter is configured to receive the first current transmitted from the semiconductor memory device, and perform an analog-to-digital conversion on the first current to obtain a first current value corresponding to the first current.

The calculator is configured to receive the first current value transmitted from the analog-to-digital converter, and determine a first computation result of the first function to be computed based on the first current value.

According to an embodiment of the present disclosure, after the pulse voltages are input to the word lines, currents are generated through the resistors on the word lines and aggregated on the bit line. The analog-to-digital converter may convert a current signal into a digital signal. The calculator may be implemented as an adder tree.

For example, when computing Softmax (x₂), according to the configuration of the pulse voltages on the word lines and the conductance values of the variable resistors shown in FIG. 6, the currents on the four bit lines are respectively subjected to analog-to-digital conversion and summed by the calculator to obtain the second computation result, i.e., the value of e^{x}^{₁}+e^{x}^{₂}+e^{x}^{₃}+e^{x}^{₄}. Further, according to the configuration of the pulse voltages on the word lines and the conductance values of the variable resistors shown in FIG. 3, the current on the bit line is subjected to analog-to-digital conversion to obtain the first computation result, i.e., the value of x₂.

By setting the second computation result as m, the computation of In (softmax (x₂)) requires calculating x₂-lnm. When calculating lnm, the Maclaurin expansion of lnm is used, i.e., calculating

$$( m - 1 ) - \frac{{( m - 1 )}^{2}}{2} + … + {( - 1 )}^{n - 1} \frac{{( m - 1 )}^{n}}{n} .$$

When using five word lines to compute the Maclaurin expansion, the pulse voltages are respectively set to 1, −½, ⅓, −¼, ⅕, and the conductance values of the variable resistors on the five word lines are respectively set to (m−1), (m−1)², (m−1)³, (m−1)⁴, (m−1)⁵. The current obtained on the bit line may be subjected to an analog-to-digital conversion, and the magnitude of the current value is equal to the value of lnm. x₂−lnm is then calculated by subtracting the third current value from the first computation result, so as to obtain the third computation result.

By setting the third computation result as n, the computation of Softmax (x₂) is transformed into the computation of e^{ln(softmax(x}^{₂}⁾⁾, i.e., the result of eⁿ. According to the configuration of the pulse voltages on the word lines as shown in FIG. 3, the pulse voltages may be respectively set to 1, n, n², n³, and the conductance values of the variable resistors on the four word lines are respectively set to 1, 1, 1/2!, 1/3!. The current obtained on the bit line is subjected to an analog-to-digital conversion, and the fourth computation result representing the magnitude of the current value is the value of eⁿ, thereby achieving the computation of Softmax (x₂).

Based on the above-described method and system for performing function computation based on in-memory computing, the present disclosure further provides an apparatus for performing function computation based on in-memory computing. The apparatus will be described in detail below with reference to FIG. 8.

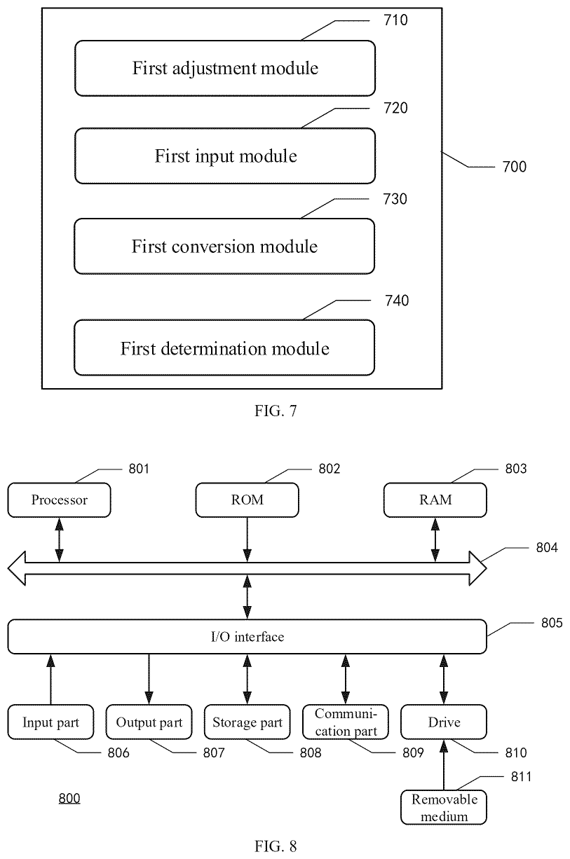

FIG. 7 schematically shows a structural block diagram of an apparatus for performing function computation based on in-memory computing according to an embodiment of the present disclosure.

As shown in FIG. 7, an apparatus 700 for performing function computation based on in-memory computing in this embodiment includes a first adjustment module 710, a first input module 720, a first conversion module 730, and a first determination module 740.

The first adjustment module 710 is configured to adjust, for a first power term in a first Taylor expansion of a first function to be computed, a first conductance value of a variable resistor on a word line corresponding to the first power term in a semiconductor memory device, according to a coefficient value of a first coefficient corresponding to the first power term. In an embodiment, the first adjustment module 710 may be configured to execute the operation S210 described above, which will not be repeated here.

The first input module 720 is configured to input a pulse voltage to the word line through the variable resistor in the semiconductor memory device according to a value of the first power term, to obtain a first current output on a bit line. In an embodiment, the first input module 720 may be configured to execute the operation S220 described above, which will not be repeated here.

The first conversion module 730 is configured to perform an analog-to-digital conversion on the first current to obtain a first current value corresponding to the first current. In an embodiment, the first conversion module 730 may be configured to execute the operation S230 described above, which will not be repeated here.

The first determination module 740 is configured to determine a first computation result of the first function to be computed based on the first current value. In an embodiment, the first determination module 740 may be configured to execute the operation S240 described above, which will not be repeated here.

According to an embodiment of the present disclosure, the first adjustment module 710 includes a first determination unit and a first adjustment unit.

The first determination unit is configured to determine the variable resistor on the word line corresponding to the first power term according to an exponent value of the first power term in the first Taylor expansion.

The first adjustment unit is configured to adjust the first conductance value of the variable resistor corresponding to the first power term in the semiconductor memory device according to the coefficient value of the first coefficient.

According to an embodiment of the present disclosure, the first input module 720 includes a second determination unit, an input unit, and an aggregating unit.

The second determination unit is configured to determine the word line corresponding to the first power term from a plurality of word lines according to the exponent value of the first power term in the first Taylor expansion.

The input unit is configured to input a pulse voltage corresponding to the coefficient value of the first coefficient to the word line corresponding to the first power term according to the value of the first power term.

The aggregating unit is configured to aggregate, for each bit line, the currents on a plurality of word lines associated with the bit line to obtain the first current output on the bit line.

According to an embodiment of the present disclosure, the apparatus 700 for performing function computation based on in-memory computing further includes a second adjustment module, a second input module, a second conversion module, and a second determination module.

The second adjustment module is configured to adjust, for the first power term in the first Taylor expansion of the first function to be computed, a second conductance value of the variable resistor on the word line corresponding to the first power term in the semiconductor memory device, according to the value of the first power term.

The second input module is configured to input a pulse voltage to the word line through the variable resistor in the semiconductor memory device according to the coefficient value of the first coefficient corresponding to the first power term, to obtain a second current output on the bit line.

The second conversion module is configured to perform an analog-to-digital conversion on the first current to obtain a second current value corresponding to the first current.

The second determination module is configured to determine a second computation result of the first function to be computed based on the second current value.

According to an embodiment of the present disclosure, the second adjustment module includes a third determination unit and a second adjustment unit.

The third determination unit is configured to determine the variable resistor on the word line corresponding to the first power term, according to the exponent value of the first power term in the first Taylor expansion.

The second adjustment unit is configured to adjust the second conductance value of the variable resistor corresponding to the first power term in the semiconductor memory device according to the value of the first power term in the first Taylor expansion.

According to an embodiment of the present disclosure, the second determination module includes a summation unit.

The summation unit is configured to sum a plurality of second current values to obtain the second computation result.

According to an embodiment of the present disclosure, the apparatus 700 for performing function computation based on in-memory computing further includes a third determination module, a third adjustment module, a third input module, a third conversion module, and a fourth determination module.

The third determination module is configured to determine each second power term in a Maclaurin expansion of a second function to be computed based on the second computation result.

The third adjustment module is configured to adjust, for each second power term, a third conductance value of a variable resistor on a word line corresponding to the second power term in the semiconductor memory device, according to a value of the second power term.

The third input module is configured to input a pulse voltage to the word line in the semiconductor memory device according to a coefficient value of a second coefficient corresponding to the second power term, to obtain a third current output on the bit line.

The third conversion module is configured to perform an analog-to-digital conversion on the third current to obtain a third current value corresponding to the third current.

The fourth determination module is configured to determine a third computation result based on the third current value and the first computation result.

According to an embodiment of the present disclosure, the apparatus 700 for performing function computation based on in-memory computing further includes a fifth determination module, a fourth adjustment module, a fourth input module, a fourth conversion module, and a sixth determination module.

The fifth determination module is configured to determine, based on the third computation result, each third power term in a second Taylor expansion of a third function to be computed.

The fourth adjustment module is configured to adjust, for each third power term, a fourth conductance value of a variable resistor on a word line corresponding to the third power term in the semiconductor memory device, according to a coefficient value of a third coefficient corresponding to the third power term.

The fourth input module is configured to input a pulse voltage to the word line in the semiconductor memory device according to a value of the third power term, to obtain a fourth current output on the bit line.

The fourth conversion module is configured to perform an analog-to-digital conversion on the fourth current to obtain a fourth current value corresponding to the fourth current.

The sixth determination module is configured to determine a fourth computation result of the third function to be computed based on the fourth current value.

According to an embodiment of the present disclosure, any number of the first adjustment module 710, the first input module 720, the first conversion module 730, and the first determination module 740 may be combined into one module for implementation, or any one of the modules may be split into a plurality of modules. Alternatively, at least part of the functions of one or more of these modules may be combined with at least part of the functions of other modules and implemented in one module. According to an embodiment of the present disclosure, at least one of the first adjustment module 710, the first input module 720, the first conversion module 730, and the first determination module 740 may be at least partially implemented as a hardware circuit, such as a field-programmable gate array (FPGA), a programmable logic array (PLA), a system on a chip, a system on a substrate, a system on a package, an application-specific integrated circuit (ASIC), or may be implemented by hardware or firmware in any other reasonable manner of integrating or packaging circuits, or may be implemented by any one of the three implementation modes of software, hardware and firmware or an appropriate combination thereof. Alternatively, at least one of the first adjustment module 710, the first input module 720, the first conversion module 730, and the first determination module 740 may be at least partially implemented as a computer program module that may perform corresponding functions when executed.

FIG. 8 schematically shows a block diagram of an electronic device suitable for implementing the method for performing function computation based on in-memory computing according to an embodiment of the present disclosure.

As shown in FIG. 8, an electronic device 800 according to an embodiment of the present disclosure includes a processor 801, which may execute various appropriate actions and processes according to a program stored in a read only memory (ROM) 802 or a program loaded into a random access memory (RAM) 803 from a storage part 808. The processor 801 may, for example, include a general-purpose microprocessor (for example, CPU), an instruction set processor and/or a related chipset and/or a special-purpose microprocessor (for example, an application specific integrated circuit (ASIC)), and the like. The processor 801 may further include an on-board memory for caching purposes. The processor 801 may include a single processing unit or multiple processing units for executing different actions of the method flow according to embodiments of the present disclosure.

Various programs and data required for the operation of the electronic device 800 are stored in the RAM 803. The processor 801, the ROM 802 and the RAM 803 are connected to each other through a bus 804. The processor 801 executes various operations of the method flow according to embodiments of the present disclosure by executing the programs in the ROM 802 and/or the RAM 803. It should be noted that the program may also be stored in one or more memories other than the ROM 802 and the RAM 803. The processor 801 may also execute various operations of the method flow according to embodiments of the present disclosure by executing the programs stored in the one or more memories.

According to embodiments of the present disclosure, the electronic device 800 may further include an input/output (I/O) interface 805 which is also connected to the bus 804. The device 800 may further include one or more of the following components connected to the I/O interface 805: an input part 806 including a keyboard, a mouse, etc.; an output part 807 including a cathode ray tube (CRT), a liquid crystal display (LCD), etc. and a speaker, etc.; a storage part 808 including a hard disk, etc.; and a communication part 809 including a network interface card such as a LAN card, a modem, and the like. The communication part 809 performs communication processing via a network such as the Internet. A drive 810 is also connected to the I/O interface 805 as required. A removable medium 811, such as a magnetic disk, an optical disk, a magneto-optical disk, a semiconductor memory, and the like, is installed on the drive 810 as required, so that the computer program read therefrom is installed into the storage part 808 as needed.

The present disclosure further provides a computer-readable storage medium, which may be included in the apparatus/device/system described in the above embodiments; or exist alone without being assembled into the apparatus/device/system. The above-mentioned computer-readable storage medium carries one or more programs that when executed, perform the methods according to embodiments of the present disclosure.

According to embodiments of the present disclosure, the computer-readable storage medium may be a non-transitory computer-readable storage medium, for example, may include but not limited to: a portable computer disk, a hard disk, a random access memory (RAM), a read-only memory (ROM), an erasable programmable read-only memory (EPROM or flash memory), a portable compact disk read-only memory (CD-ROM), an optical storage device, a magnetic storage device, or any suitable combination of the above. In the present disclosure, the computer-readable storage medium may be any tangible medium that contains or stores programs that may be used by or in combination with an instruction execution system, apparatus or device. For example, according to embodiments of the present disclosure, the computer-readable storage medium may include the above-mentioned ROM 802 and/or RAM 803 and/or one or more memories other than the ROM 802 and RAM 803.

Embodiments of the present disclosure further include a computer program product, which contains a computer program. The computer program contains program codes for performing the methods shown in the flowcharts. When the computer program product runs on a computer system, the program codes cause the computer system to implement the methods provided in embodiments of the present disclosure.

When the computer program is executed by the processor 801, the above-mentioned functions defined in the system/apparatus of the embodiments of the present disclosure are performed. According to embodiments of the present disclosure, the above-described systems, apparatuses, modules, units, etc. may be implemented by computer program modules.

In an embodiment, the computer program may rely on a tangible storage medium such as an optical storage device and a magnetic storage device. In another embodiment, the computer program may also be transmitted and distributed in the form of signals on a network medium, downloaded and installed through the communication part 809, and/or installed from the removable medium 811. The program code contained in the computer program may be transmitted by any suitable network medium, including but not limited to a wireless one, a wired one, or any suitable combination of the above.

In such embodiments, the computer program may be downloaded and installed from the network through the communication part 809, and/or installed from the removable medium 811. When the computer program is executed by the processor 801, the above-mentioned functions defined in the system of embodiments of the present disclosure are performed. According to embodiments of the present disclosure, the above-described systems, apparatuses, devices, modules, units, etc. may be implemented by computer program modules.

According to embodiments of the present disclosure, the program codes for executing the computer programs provided by embodiments of the present disclosure may be written in any combination of one or more programming languages. In particular, these computing programs may be implemented using high-level procedures and/or object-oriented programming languages, and/or assembly/machine languages. Programming languages include, but are not limited to, Java, C++, Python, “C” language or similar programming languages. The program code may be completely executed on the user computing device, partially executed on the user device, partially executed on the remote computing device, or completely executed on the remote computing device or server. In a case of involving a remote computing device, the remote computing device may be connected to a user computing device through any kind of network, including a local area network (LAN) or a wide area networks (WAN), or may be connected to an external computing device (e.g., through the Internet using an Internet service provider).

The flowcharts and block diagrams in the accompanying drawings illustrate the possible architecture, functions, and operations of the system, method, and computer program product according to various embodiments of the present disclosure. In this regard, each block in the flowcharts or block diagrams may represent a part of a module, a program segment, or a code, which part includes one or more executable instructions for implementing the specified logical function. It should be further noted that, in some alternative implementations, the functions noted in the blocks may also occur in a different order from that noted in the accompanying drawings. For example, two blocks shown in succession may actually be executed substantially in parallel, or they may sometimes be executed in a reverse order, depending on the functions involved. It should be further noted that each block in the block diagrams or flowcharts, and the combination of blocks in the block diagrams or flowcharts, may be implemented by a dedicated hardware-based system that performs the specified functions or operations, or may be implemented by a combination of dedicated hardware and computer instructions.

Those skilled in the art may understand that the features described in various embodiments and/or the claims of the present disclosure may be combined or integrated in various ways, even if such combinations or integrations are not explicitly described in the present disclosure. In particular, the features described in various embodiments and/or the claims of the present disclosure may be combined and/or integrated in various ways without departing from the spirit and teachings of the present disclosure. All these combinations and/or integrations fall within the scope of the present disclosure.

Embodiments of the present disclosure have been described above. However, these embodiments are for illustrative purposes only, and are not intended to limit the scope of the present disclosure. Although the various embodiments have been described separately above, this does not mean that measures in the respective embodiments may not be used in combination advantageously. The scope of the present disclosure is defined by the appended claims and their equivalents. Those skilled in the art may make various substitutions and modifications without departing from the scope of the present disclosure, and these substitutions and modifications should all fall within the scope of the present disclosure.

1. A method for performing function computation based on in-memory computing, comprising: for a first power term in a first Taylor expansion of a first function to be computed,
adjusting, according to a coefficient value of a first coefficient corresponding to the first power term, a first conductance value of a variable resistor on a word line corresponding to the first power term in a semiconductor memory device;
inputting, according to a value of the first power term, a pulse voltage to the word line through the variable resistor in the semiconductor memory device, so as to obtain a first current output on a bit line;
performing an analog-to-digital conversion on the first current to obtain a first current value corresponding to the first current; and
determining a first computation result of the first function to be computed based on the first current value.

2. The method of claim 1, wherein the adjusting, according to a coefficient value of a first coefficient corresponding to the first power term, a first conductance value of a variable resistor on a word line corresponding to the first power term in a semiconductor memory device comprises:
determining the variable resistor on the word line corresponding to the first power term according to an exponent value of the first power term in the first Taylor expansion; and
adjusting, according to the coefficient value of the first coefficient, the first conductance value of the variable resistor corresponding to the first power term in the semiconductor memory device.

3. The method of claim 1, wherein the inputting, according to a value of the first power term, a pulse voltage to the word line through the variable resistor in the semiconductor memory device, so as to obtain a first current output on a bit line comprises:
determining the word line corresponding to the first power term from a plurality of word lines according to an exponent value of the first power term in the first Taylor expansion;
inputting, according to the value of the first power term, a pulse voltage corresponding to the coefficient value of the first coefficient to the word line corresponding to the first power term; and
aggregating, for each bit line, currents on a plurality of word lines associated with the bit line to obtain the first current output on the bit line.

4. The method of claim 1, further comprising: for each first power term in the first Taylor expansion of the first function to be computed,
adjusting, according to the value of the first power term, a second conductance value of the variable resistor on the word line corresponding to the first power term in the semiconductor memory device;
inputting, according to the coefficient value of the first coefficient corresponding to the first power term, a pulse voltage to the word line through the variable resistor in the semiconductor memory device, so as to obtain a second current output on the bit line;
performing an analog-to-digital conversion on the second current to obtain a second current value corresponding to the second current; and
determining a second computation result of the first function to be computed based on the second current value.

5. The method of claim 4, wherein the adjusting, according to the value of the first power term, a second conductance value of the variable resistor on the word line corresponding to the first power term in the semiconductor memory device comprises:
determining the variable resistor on the word line corresponding to the first power term according to an exponent value of the first power term in the first Taylor expansion; and
adjusting, according to the value of the first power term in the first Taylor expansion, the second conductance value of the variable resistor corresponding to the first power term in the semiconductor memory device.

6. The method of claim 4, wherein the first function to be computed comprises a plurality of first Taylor expansions, and the determining a second computation result of the first function to be computed based on the second current value comprises:
summing a plurality of second current values to obtain the second computation result.

7. The method of claim 1, further comprising:
determining, based on the second computation result, each second power term in a Maclaurin expansion of a second function to be computed;
adjusting, for each second power term, a third conductance value of a variable resistor on a word line corresponding to the second power term in the semiconductor memory device, according to a value of the second power term;
inputting a pulse voltage to the word line in the semiconductor memory device according to a coefficient value of a second coefficient corresponding to the second power term, so as to obtain a third current output on the bit line;
performing an analog-to-digital conversion on the third current to obtain a third current value corresponding to the third current; and
determining a third computation result based on the third current value and the first computation result.

8. The method of claim 1, further comprising:
determining, based on the third computation result, each third power term in a second Taylor expansion of a third function to be computed;
adjusting, for each third power term, a fourth conductance value of a variable resistor on a word line corresponding to the third power term in the semiconductor memory device, according to a coefficient value of a third coefficient corresponding to the third power term;
inputting a pulse voltage to the word line in the semiconductor memory device according to a value of the third power term, so as to obtain a fourth current output on the bit line;
performing an analog-to-digital conversion on the fourth current to obtain a fourth current value corresponding to the fourth current; and
determining a fourth computation result of the third function to be computed based on the fourth current value.

9. (canceled)

10. A system for performing function computation based on in-memory computing, comprising:
a semiconductor memory device, comprising a word line and a bit line, wherein a variable resistor is provided on the word line; the semiconductor memory device is configured to receive a pulse voltage on the bit line and to obtain, through the variable resistor on the word line, a first current output on the bit line, a first conductance value of the variable resistor is adjusted according to a coefficient value of a first coefficient corresponding to a first power term, and a voltage value of the pulse voltage is determined according to a value of the first power term;
an analog-to-digital converter configured to receive the first current transmitted from the semiconductor memory device, and to perform an analog-to-digital conversion on the first current to obtain a first current value corresponding to the first current; and
a calculator configured to receive the first current value transmitted from the analog-to-digital converter, and to determine a first computation result of a first function to be computed based on the first current value.
